(19) United States
(12) Patent Application Publication
(10) Pub. No.: US 2016/0274468 A1
(43) Pub. Date: Sep. 22, 2016

(54) METHOD FOR FORMING PATTERN

(71) Applicant: KABUSHIKI KAISHA TOSHIBA, Tokyo (JP)

(72) Inventors: Ryoichi SUZUKI, Yokohama (JP); Sachiko KOBAYASHI, Tokyo (JP)

(21) Appl. No.: 14/840,818

(22) Filed: Aug. 31, 2015

(30) Foreign Application Priority Data
Mar. 16, 2015 (JP) 2015-052748

(51) Int. Cl. G03F 7/20

(52) U.S. Cl. CPC G03F 7/70058

(57) ABSTRACT

According to an embodiment, a method for forming a pattern includes selectively forming a first film on a first region on a substrate. The first region is included in an optical interference area of a first light and a second light on the substrate. The first light passes through a first passing portion of a diffraction mask and the second light passes through a second passing portion of the diffraction mask. The method further includes exposing the first film to optical interference light generated by at least the first light and the second light.

### CROSS-REFERENCE TO RELATED APPLICATIONS

This application is based upon and claims the benefit of priority from Japanese Patent Application No. 2015-052748, filed on Mar. 16, 2015; the entire contents of which are incorporated herein by reference.

### FIELD

Embodiments are generally related to a method for forming a pattern.

### BACKGROUND

In a manufacturing process of semiconductor devices, MEMS (Micro Electro Mechanical Systems), or the like, photolithographic techniques are used to form fine patterns thereof. One of the photolithographic techniques is an optical interference lithography using an optical image provided by an optical interference, for example. The optical interference lithography makes it possible to form a pattern having low roughness, for example. However, the optical interference image may contain disorder at the periphery thereof, and thus, it is difficult in the optical interference lithography to obtain uniformity over the whole pattern.

### BRIEF DESCRIPTION OF THE DRAWINGS

FIGS. 1A and 1B are schematic views showing a photosensitive film using a method for forming a pattern according to an embodiment;

FIG. 2 is a schematic cross-sectional view showing optical interference lithography according to the embodiment;

FIG. 3 is a flow chart showing the method for forming a pattern according to the embodiment;

FIGS. 4A to 4D are schematic cross-sectional views showing a method for forming the photosensitive film according to the embodiment;

FIGS. 5A to 5C are schematic plan views showing a transfer pattern, a diffraction mask, and a photosensitive film according to the embodiment; and

FIGS. 6A and 6B are schematic cross-sectional views showing other optical interference lithography methods according to the embodiment.

### DETAILED DESCRIPTION

According to an embodiment, a method for forming a pattern includes selectively forming a first film on a first region on a substrate. The first region is included in an optical interference area of a first light and a second light on the substrate. The first light passes through a first passing portion of a diffraction mask and the second light passes through a second passing portion of the diffraction mask. The method further includes exposing the first film to optical interference light generated by at least the first light and the second light.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

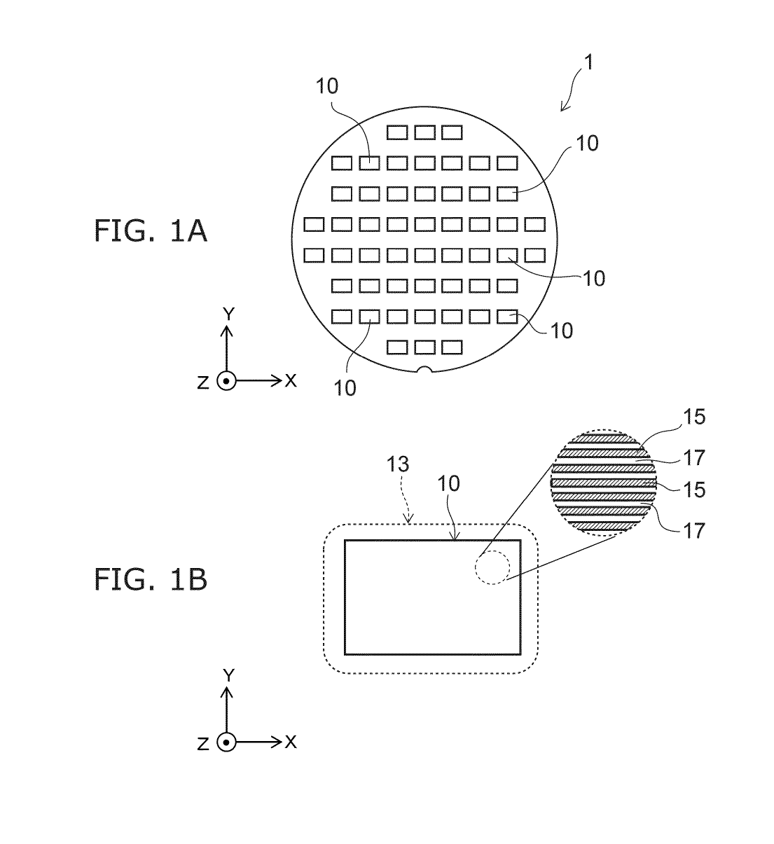

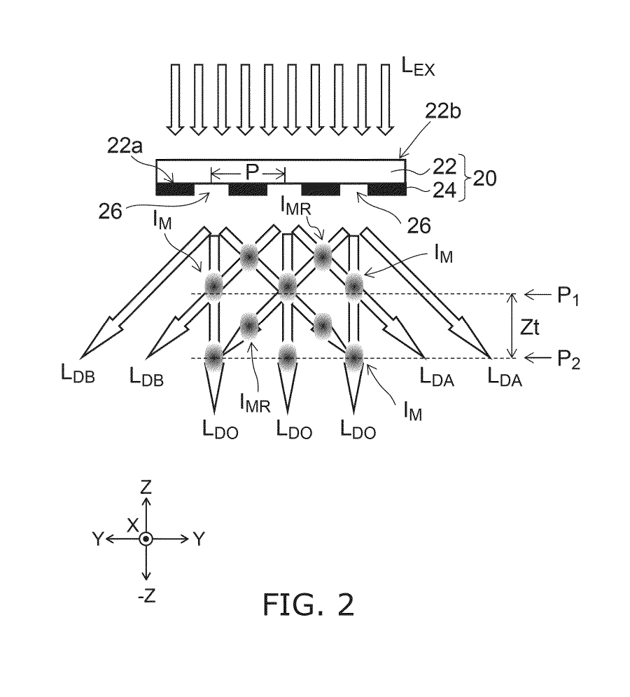

With reference to FIG. 1A, FIG. 1B, and FIG. 2, a method for forming a pattern according to an embodiment will be described.

FIG. 1A is a schematic plan view showing photosensitive films 10 formed on a substrate 1.

FIG. 1B is a schematic plan view showing a photosensitive film 10 corresponding to an irradiation area of exposure light

FIG. 2 is a schematic cross-sectional view showing a diffraction mask 20 and the exposure light that pass through the diffraction mask 20.

As shown in FIG. 1A, first films (hereinafter, photosensitive films 10) are formed selectively on the substrate 1. The substrate 1 is a silicon substrate, for example. The photosensitive films 10 are negative-type photo-resist films, for example.

The photosensitive film 10 is formed in a predetermined region on a device formed on the substrate 1 or a region where a device is to be provided, for example. The photosensitive films 10 are disposed with the first interval in a first direction (hereinafter, X-direction) and with the second interval in a second direction (hereinafter, Y-direction). The X-direction and the Y-direction are parallel to the surface of the substrate 1. A disposition pitch of the photosensitive films 10 coincides with a device pattern pitch on the substrate 1.

In a method for forming a pattern according to an embodiment, the diffraction mask 20 causes optical interference of the exposure light. The diffraction mask 20 includes first light passing portions (hereinafter, light passing portions 26), and at least two parts of the exposure light each passing through the light passing portions 26 (i.e. a first exposure light and a second exposure light) cause the optical interference of on the substrate 1 (refer to FIG. 2). The photosensitive film 10 is formed selectively on a first interference area in the substrate, where the first exposure light and a second exposure light interfere with each other. That is, the photosensitive film 10 is exposed to an interfering light generated by the first and second exposure lights which interfere with each other on the interfering area. As a result, an interference pattern formed by the interference of the first and second exposure lights is transferred onto the photosensitive film 10.

As shown in FIG. 1B, the photosensitive film 10 is provided with a size so as to occupy the region inside an interference area 13. That is, the photosensitive film 10 has a size smaller than a size of the interference area 13 on the substrate 1. Here, the interference area 13 coincides with a whole area where at least two exposure lights that pass through the light passing portions 26 of the diffraction mask 20 interfere with each other, for example. Further, during the exposure, an interference pattern is formed on the interference area 13, which includes a bright region 15 and a dark region 17 which extend in the X-direction in a stripe pattern, for example. A line-and-space pattern is transferred to the photosensitive film 10. The line pattern corresponding to the bright region 15 and the space therebetween corresponding to the dark region 17 are formed alternately in the Y-direction, for example.

As shown in FIG. 2, the diffraction mask 20 includes a transparent substrate 22 and light blocking films 24, for example. The light passing portion 26 is provided between the light blocking films 24 arranged side by side in the Y-direction. The transparent substrate 22 is a silica glass plate, for example. The light blocking film 24 is a metal chromium film or a chromium oxide film, for example.

The transparent substrate 22 has a first face 22a and a second face 22b opposite to the first face 22a. The light blocking films 24 are formed on the first face 22a and arranged with the same interval in the Y-direction, for example. The light passing portion 26 is formed between the adjacent light blocking films 24. The light blocking film 24 and the light passing portion 26 extend in the X-direction, for example.

As shown in FIG. 2, the second face 22b of the diffraction mask 20 is irradiated with the exposure light L_{EX}. Preferably, a coherent light is used for the exposure light L_{EX}, for example. A laser light is used for the exposure light L_{EX}, for example.

The exposure light L_{EX} passes through the light passing portions 26 of the diffraction mask 20, and the substrate 1 disposed on the first face 22a side is irradiated with the exposure light L_{EX}. The exposure light L_{EX} that has passed through the light passing portions 26 includes a 0th-order diffracted light L_{D0}, a +1st-order diffracted light L_{DA}, and a −1st-order diffracted light L_{DB}, for example. The 0th-order diffracted light L_{D0} propagates straight in a −Z-direction after passing through the light passing portions 26. The +1st-order diffracted light L_{DA} is diffracted in the Y-direction, and the −1st-order diffracted light L_{DB} is diffracted in the −Y direction.

As shown in FIG. 2, a direct image I_{M} is formed at a position where the 0th-order diffracted light LD₀, the +1st-order diffracted light L_{DA}, and the −1st-order diffracted light L_{DB} overlap with one another. Further, a reversed image I_{MR} is formed at a position where the +1st-order diffraction light L_{DA} and the −1st-order diffraction light L_{DB} overlap with each other.

The direct image I_{M} means a bright image formed at a position corresponding to the light passing portion 26. For example, the direct images I_{M} are formed with the same interval in the Y-direction in each of virtual planes P₁ and P₂ shown by dotted lines in FIG. 2. The period of the direct images I_{M} arranged in the Y-direction is the same as the period P of the light passing portions 26 arranged in the Y-direction. When the substrate 1 is disposed so that a surface of the photosensitive film 10 is placed in the virtual plane P₁ or P₂, for example, it is possible to expose the photosensitive film 10 to the direct image I_{M}. That is, the photosensitive film 10 is exposed to the interference light that has a pattern corresponding to the pattern provided on the diffraction mask 20.

The direct images I_{M} are also formed in the −Z-direction periodically. The period of the direct images IM in the −Z-direction is equal to a spacing Zt between P₁ and P₂. Zt is a so-called Talbot distance, and expressed by formulas (1) and (2). Here, the wavelength of the exposure light L_{EX} is defined as λ, and the period of the light passing portions 26 on the diffraction mask 20 is defined as P.

When the diffraction mask 20 is irradiated with the exposure light L_{EX} having the wavelength λ that is close to the period P, Zt is expressed by the formula (1).

$$Zt = \frac{{P}^{2}}{λ} ( 1 + \sqrt{1 - {( \frac{λ}{P} )}^{2}} ) \qquad ( 1 )$$

Further, when the pitch P is not less than two times of the wavelength λ, Zt is approximately expressed by the formula (2).

$$Zt \approx \frac{2 {P}^{2}}{λ} , P >> λ \qquad ( 2 )$$

Then, it is possible to expose the photosensitive film 10 to a predetermined interference pattern by placing the substrate 1 so that the distance between the photosensitive film 10 and the diffraction mask 20 is an integer multiple of Zt.

On the other hand, the reversed image I_{MR} is located at a middle position between the virtual planes P₁ and P₂. Further, the reversed image I_{MR} is a bright image formed at a position corresponding to the center of the light blocking films 24 in the Y-direction. Then, the light Intensity distribution generated by the reversed images I_{MR} arranged in the Y-direction is a reversed distribution in which the light intensity distribution generated by the direct images I_{M} is reversed. That is, when the photosensitive film 10 is placed at the middle position between P₁ and P₂, it is possible to expose the photosensitive film 10 to another interference pattern in which the pattern formed on the diffraction mask 20 is reversed.

In the optical interference lithography using the above described diffraction mask 20, the periodicity of the optical interference may be lost, for example, around the ends of the light passing portions 26 which are disposed with a constant interval. Accordingly, the interference pattern has disorder around the ends of the direct images I_{M}. In other words, the light intensity distribution has the disorder around the mask pattern of the diffraction mask 20, and uniformity is degraded in the exposed pattern on the substrate 1.

In the embodiment, the photosensitive film 10 is provided selectively on the substrate 1, and the photosensitive film 10 has a size smaller than a size of the interference region 13. Thereby, it is possible to achieve a uniform pattern using the optical interference lithography by eliminating the disorder around the mask pattern of the diffraction mask 20.

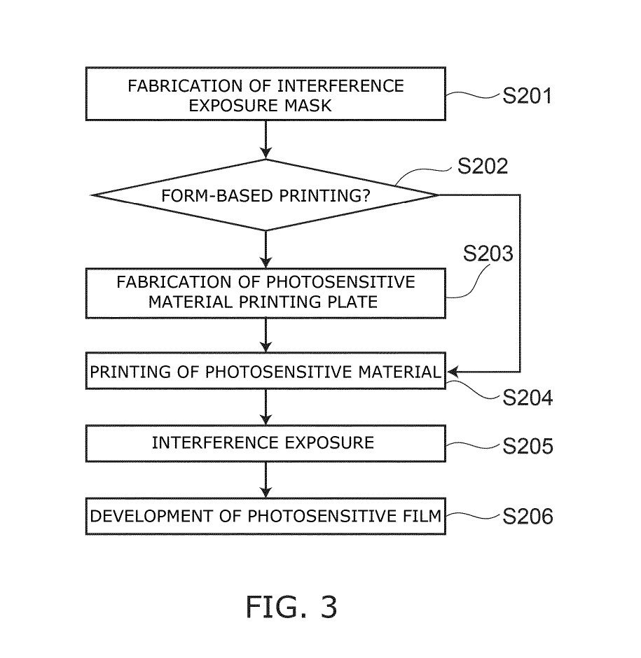

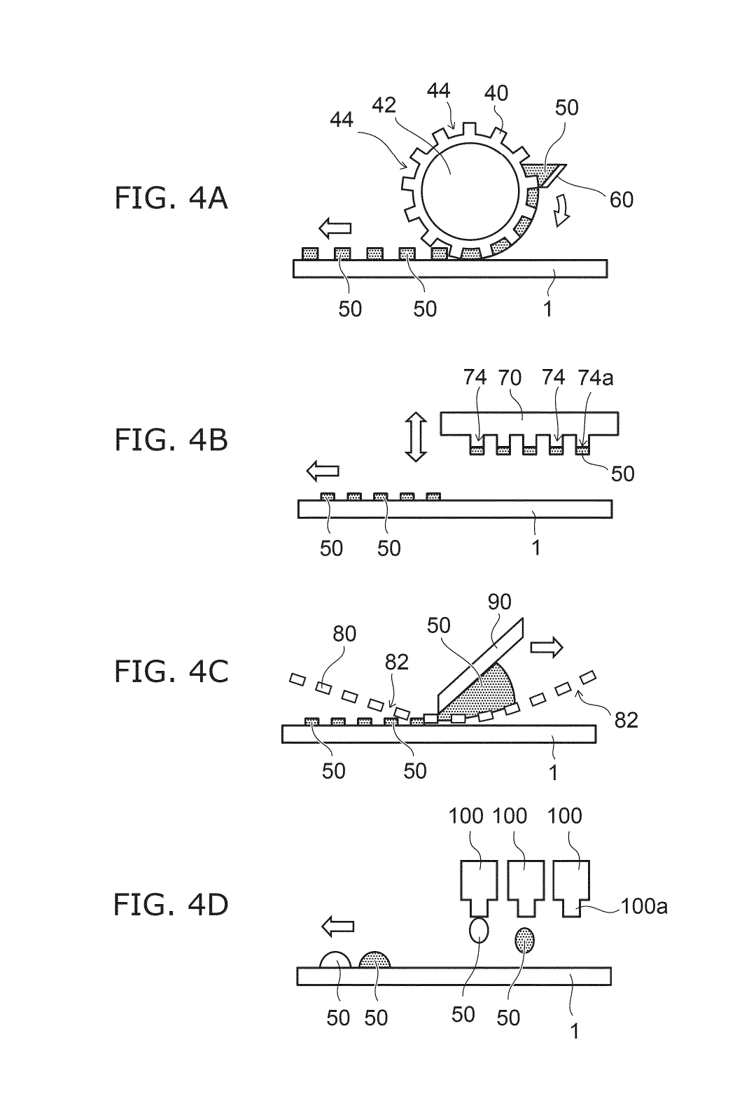

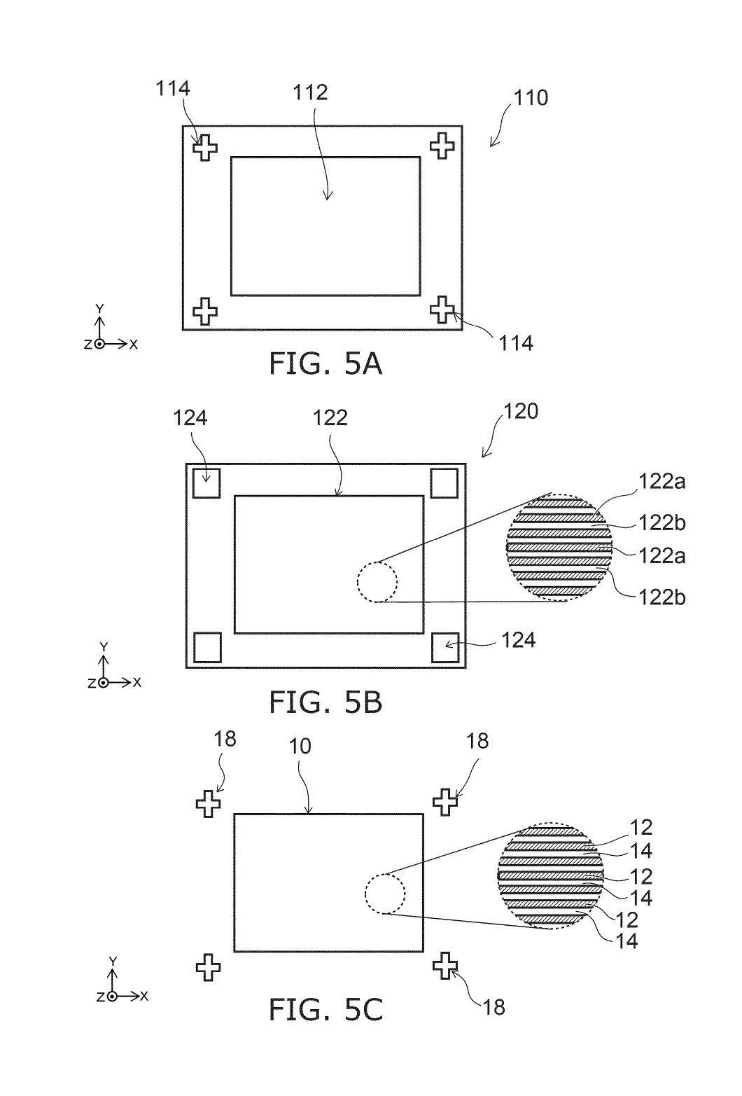

With reference to FIG. 3 to FIG. 5C, a method for forming a pattern according to an embodiment will be described. FIG. 3 is a flowchart showing the method for forming a pattern according to the embodiment. FIG. 4A to FIG. 4D are schematic cross-sectional views showing methods for forming the photosensitive film 10 according to the embodiment. FIG. 5A to FIG. 5C are schematic plan views showing a transfer pattern 110, a diffraction mask 120, and the photosensitive film 10 according to the embodiment.

As shown in FIG. 3, steps S201 to S206 are carried out for forming a pattern according to the embodiment. Each step will be described sequentially according to FIG. 3.

Step S201: providing a diffraction mask 120 used for the interference lithography. The diffraction mask 120 includes the transparent substrate 22 and the light blocking films 24. The light blocking films 24 are formed on the first face 22a of the transparent substrate 22, for example.

Step S202: selecting a method for forming the photosensitive films 10 on the substrate 1. The photosensitive films 10 are formed using one of various methods. Here, the method is selected based on whether using a printing plate or not, for example. When using the printing plate, the process goes to step S203. When not using the printing plate, the process goes to step S204.

Step S203: providing the printing plate. A photogravure printing, a micro-contact printing, a screen printing and the like may be cited as available methods. In each of these printing methods, a printing plate is required for forming a predetermined pattern on a foundation. Then, the printing plate including a predetermined pattern is provided.

Step S204: forming the photosensitive films 10 on the substrate using a selected method.

Here, the printing plate and the printing method will be described with reference to FIG. 4A to FIG. 4D. Each of FIG. 4A to FIG. 4C shows a specific example of the printing method using the printing plate.

FIG. 4A is a schematic cross-sectional view to illustrate the photogravure printing method. The photogravure printing method uses a printing plate 40, photosensitive material 50, and a squeegee 60. The printing plate 40 is set to the surface of a circular cylinder 42. The printing plate 40 has a plurality of concave portions 44 engraved on the surface thereof. The concave portions 44 are formed so that each opening thereof has the shape of the photosensitive film 10. The concave portions 44 are formed to have a pitch that is coincide with a unit length of the periodic arrangement of the photosensitive films 10.

For example, after aligning the concave portion 44 with a predetermined region on the substrate 1, the photosensitive material 50 is applied on the printing plate while rotating the circular cylinder 42. Excess parts of the photosensitive material 50 are removed using the squeegee 60 from a surface of the printing plate, filling each concave portion 44 with the photosensitive material 50. Then, the photosensitive material 50 is transferred onto a surface of the substrate 1 from the concave portions 44 while moving the substrate 1 in the A1-direction. Further, the substrate 1 is baked to evaporate a solvent of the photosensitive material 50. Thereby, the photosensitive films 10 are formed on the substrate 1.

FIG. 4B is a schematic cross-sectional view illustrating the micro-contact printing method. The micro-contact printing method uses the photosensitive material 50 and a printing plate 70. The printing plate 70 has a plurality of convex portions 74 on the surface thereof. The top surface 74a of the convex portion 74 has the shape of the photosensitive film 10. The pitch of the convex portions 74 is the same as the unit length of the periodic arrangement of the photosensitive films 10.

For example, the photosensitive material 50 is applied to each top surface of the convex portions 74. Then, the convex portion 74 is aligned with a predetermined region on the substrate 1, and the photosensitive material 50 is transferred by making the top surface of the convex portions 74 in contact with the surface of the substrate 1. The substrate 1 is baked to evaporate a solvent of the photosensitive material 50, forming the photosensitive films 10 thereon.

FIG. 4C is a schematic cross-sectional view illustrating the screen printing method. The screen printing method uses the photosensitive material 50, a printing screen 80, and a squeegee 90. The printing screen 80 is disposed above the substrate 1. The printing screen 80 has a plurality of through-holes 82. Each opening of the through-holes 82 has the shape of the photosensitive film 10. The pitch of the through-holes 82 is the same as the unit length of the periodic arrangement of the photosensitive films 10.

The through-hole 82 is aligned with a predetermined region on the substrate 1. Then, the photosensitive material 50 is supplied onto the printing plate 80, and the photosensitive material 50 is pushed out from the through-holes 82 using the squeegee 90. The photosensitive material 50 is transferred onto the substrate 1 through the through-holes 82. The substrate 1 is baked to evaporate a solvent of the photosensitive material 50, forming the photosensitive films 10 thereon.

FIG. 4D is a schematic cross-sectional view illustrating an ink-jet printing method. The ink-jet printing method does not use the printing plate. When the printing method not using the printing plate is selected in step S202, the photosensitive films 10 may be formed using the ink-jet printing method. In the ink-jet printing method, the photosensitive material 50 is applied using a nozzle 100 to a predetermined region on the substrate 1.

The nozzle 100 is aligned with a predetermined region on the substrate 1, and the photosensitive material 50 is ejected from an ejection portion 100a of the nozzle 100. Then, the substrate 1 is slid to eject the photosensitive material 50 on another position. After completing the ejections of the photosensitive material 50, the substrate 1 is baked to evaporate a solvent of the photosensitive material 50, forming photosensitive film 10 thereon.

FIG. 5A is a schematic plan view illustrating a transfer pattern 110 formed in the printing plate. For example, the transfer pattern 110 illustrates the concave portion 44 of the photogravure printing plate 40 or the through-hole 82 of the printing screen 80, for example.

The transfer pattern 110 has a first opening portion 112 and a second opening portion 114, and enables a first photosensitive material and a second photosensitive material to be transferred onto the substrate 1, for example. The first photosensitive material forms the photosensitive film 10, for example, and is transferred via the first opening portion 112. The second photosensitive material is transferred to a region separated from the first photosensitive material via the second opening portion 114. The first photosensitive material is transferred onto a first region on the substrate 1, and the second photosensitive material is transferred onto a second region separated from the first region. The first opening portion 112 is formed to have a size smaller than a size of the interference region 13 (see FIG. 1B). The second opening portion 114 has a shape of an alignment mark 18 (see FIG. 5C), for example. The second opening portion 114 is formed close to each of the four corners of the first opening portion 112, for example. The second opening portion 114 has a cross shape, for example.

Step S205: exposing the photosensitive film 10 to the interference light using the diffraction mask 120. For example, FIG. 5B is a schematic plan view illustrating the diffraction mask 120. The diffraction mask 120 includes a grating 122 and an opening portion 124. The exposure light L_{EX} may be directly irradiate the substrate 1 without interference through the opening portion 124.

The grating 122 includes light blocking portions 122a and light passing portions 122b. The light blocking portions 122a and the light passing portions 122b are provided with a stripe shape extending in the X-direction, for example. The light blocking portions 122a and the light passing portions 122b are alternately disposed in the Y-direction. That is, the light blocking portions 122a are disposed with a constant interval in the Y-direction. The grating 122 has a size larger than a size of the first opening portion 112 of the transfer pattern 110.

The opening portion 124 is disposed close to each of the four corners of the grating 122, for example. The opening portion 124 is provided at a position where the opening portion 124 overlaps with the second opening portion 114 of the transfer pattern 110. The opening portion 124 has a size larger than a size of the second opening portion 114. That is, the opening portion 124 is larger than the second region on the substrate 1.

Next, a procedure of exposing the first photosensitive material (first film: photosensitive film 10) and the second photosensitive material (second film) using the diffraction mask 120 will be described. The grating 122 is aligned with the first photosensitive material transferred onto the substrate 1. For example, the position of the diffraction mask 120 is aligned so that the second photosensitive material (hereinafter, alignment mark 18) is placed inside the opening portion 124 of the diffraction mask 120. The alignment mark 18 is formed on the substrate through the second opening portion 114 of the transfer pattern 110. Then, the diffraction mask 120 is irradiated with the exposure light L_{EX} on the second face side (see FIG. 2).

For example, when the distance between the diffraction mask 120 and the photosensitive film 10 is an integer multiple of Zt, a direct image of the grating 122 is transferred to the photosensitive film 10. Alternatively, when the distance between the diffraction mask 120 and the photosensitive film 10 is an integer multiple of Zt+Zt/2, a reversed image of the grating 122 is transferred to the photosensitive film 10.

Step S206: developing the photosensitive film 10 exposed to the exposure light L_{EX}. For example, FIG. 5C is a schematic plan view showing the photosensitive film 10 and the alignment mark 18 after the development.

As shown in FIG. 5C, a developed pattern is formed in the photosensitive film 10 corresponding to the grating 122. For example, when the photosensitive material 50 is a negative resist and the direct images I_{M} are transferred thereto, a pattern corresponding to the light passing portions 122b remains in the photosensitive film 10. Thus, a line-and-space pattern is formed as shown in FIG. 5C, including a line pattern 12 and a space pattern 14.

The alignment mark 18 is formed by directly exposing to the exposure light L_{EX} via the opening portion 124 of the diffraction mask 120, and remains on the substrate 1. Further, when the reversed image I_{MR} is transferred, a pattern corresponding to the light blocking portions 122a remains in the photosensitive film 10.

According to the method for forming a pattern of the embodiment, the disorder of the interference pattern at the ends of the diffraction pattern may be eliminated in the transferred pattern, since the photosensitive film 10 is placed inside the interference region 13. Thereby, uniformity is improved in the transferred pattern formed by using the optical interference lithography.

Further, as shown in the embodiment, the alignment mark 18 may be formed on the substrate 1 in the process of the optical interference lithography. Thus, a positional shift between the photosensitive film 10 and the alignment mark 18 may be suppressed compared with the case where the photosensitive film 10 and the alignment mark 18 are formed respectively in a different process. Thereby, it becomes possible to improve an accuracy of the mask alignment in the following processes, and to improve the device manufacturing yield.

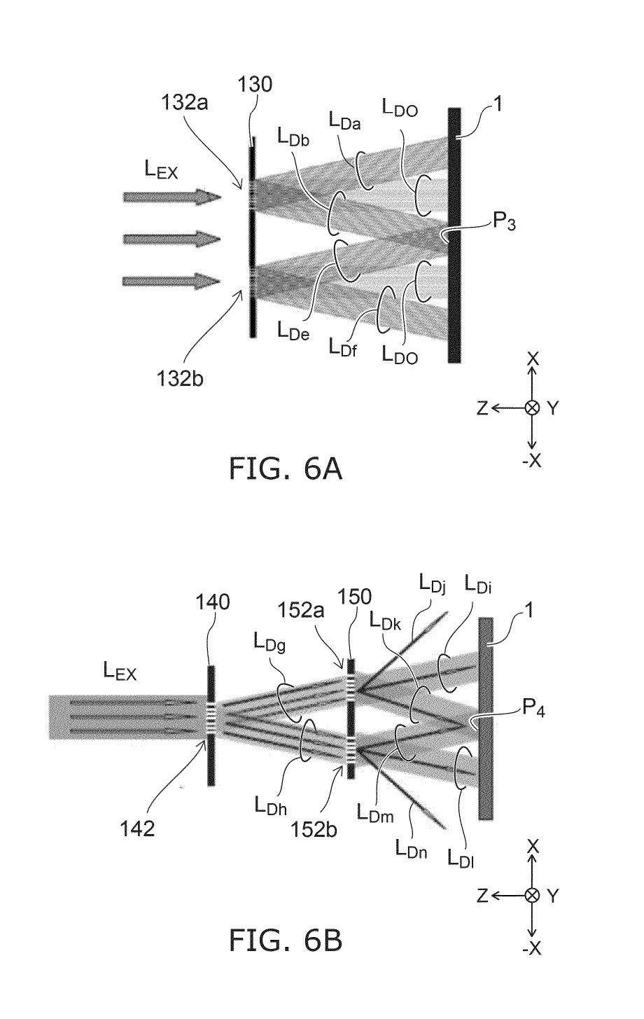

Next, other interference lithography methods will be described with reference to FIG. 6A and FIG. 6B. FIG. 6A is a schematic cross-sectional view illustrating a two-beam optical interference system. FIG. 6B is a schematic cross-sectional view illustrating another two-beam optical interference system.

In the example shown in FIG. 6A, a diffraction mask 130 is placed so as to opposite the surface of the substrate 1 on which the photosensitive films 10 are formed. The diffraction mask 130 includes two gratings 132 (hereinafter, grating 132a and grating 132b). The grating 132a and the grating 132b are disposed side by side in the X-direction. The grating 132 includes a plurality of slits extending in the Y-direction and each having an opening of a stripe shape, for example.

The diffraction mask 130 is irradiated with an exposure light L_{EX}. The exposure light L_{EX} is a EUV laser light, and is a coherent light, for example. The exposure light L_{EX} may be an extreme ultraviolet radiation having a wavelength around 13.5 nm, for example. The exposure light L_{EX} passes through each slit of the grating 132a and the grating 132b, and the substrate 1 is also irradiated with the exposure light L_{EX}.

The exposure light L_{EX} passed through the grating 132a includes 0th-order diffracted lights L_{D0}, +1st-order diffracted lights L_{Da}, and −1st-order diffracted lights L_{Db}, for example. The 0th-order diffracted lights L_{D0} are not diffracted at the slits and propagates straight toward the substrate 1 through the slits. The 1st-order diffracted lights L_{Da} and L_{Db} are diffracted in the +X-direction and the −X-direction at the slits.

The exposure light L_{EX} passed through the slits of the grating 132b includes 0th-order diffraction lights L_{D0}, +1st-order diffraction lights L_{De}, and −1st-order diffraction lights L_{Df}, for example.

As shown in FIG. 6A, the −1st-order diffraction lights L_{Db} passed through the grating 132a and the +1st-order diffraction lights L_{De} passed through the grating 132b overlap with each other on the substrate 1, causing the optical interference. Then, the photosensitive film 10 at the interference position P₃ is irradiated with the interference light of LDb and LDe. Other diffraction lights, for example, the 0th-order diffraction light L_{D0} propagates toward the vicinity of the interference position P₃, and influence of such a light may be avoided by selectively forming the photosensitive film 10 at the interference position P₃. Further, in the example, the slits of the grating 132 may be transferred as an interference pattern that has a period corresponding to a half pitch of the slits arranged in the X-direction.

In the example shown in FIG. 6B, a first diffraction mask 140 and a second diffraction mask 150 are disposed between an exposure light source (not shown) and the substrate 1. A surface of the substrate 1 faces the second diffraction mask 150. The photosensitive film 10 is provided on the surface facing the second diffraction mask 150.

The first diffraction mask 140 includes a grating 142. The second diffraction mask 150 includes two gratings 152 (hereinafter, grating 152a and grating 152b). The grating 152a and the grating 152b are disposed side by side in the X-direction. Each of the grating 152a and the grating 152b includes a plurality of slits extending in the Y-direction and each having a stripe shape, for example.

The first diffraction mask 140 is irradiated with the exposure light L_{EX}, and passes through the grating 142. The second diffraction mask 150 is irradiated with the exposure light L_{EX} passed through the grating 142. The exposure light L_{EX} passed through the grating 142 includes 0th-order diffraction lights L_{D0}, +1st-order diffraction lights L_{Dg}, and −1st-order diffraction lights L_{Dh}.

The +1st-order diffraction lights L_{Dg} propagate toward the grating 152a of the second diffraction mask 150, and the −1st-order diffraction lights L_{Dh} propagate toward the grating 152b of the second diffraction mask 150. The 0th-order diffraction light L_{D0} is blocked by the second diffraction mask 150 and does not reach the substrate 1. Accordingly, the 0th-order diffraction lights L_{D0} are omitted from FIG. 6B.

The +1st-order diffraction lights L_{Dg} pass through the grating 152a, and propagate as 0th-order diffracted lights L_{Di}, +1st-order diffracted lights L_{Dj}, and −1st-order diffracted lights L_{Dk}, for example. The −1st-order diffracted lights L_{Dm} pass through the grating 152b and propagate as 0th-order diffracted light L_{Dl}, +1st-order diffracted lights L_{Dm}, and −1st-order diffracted lights L_{Dn}, for example.

As shown in FIG. 6B, the −1st-order diffracted lights L_{Dk} and the +1st-order diffracted lights L_{Dm} propagate toward the substrate 1 at an interference position P₄ after passing through the gratings 152a and 152b respectively. Accordingly, it is possible to expose the photosensitive film 10 to the interference patterns of the −1st-order diffraction lights L_{Dk} and the +1st-order diffraction lights L_{Dm}. In the interference lithography system shown in FIG. 6B, a resolution of the interference pattern may become higher than a resolution in the system shown in FIG. 6A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for forming a pattern, comprising:
selectively forming a first film on a first region on a substrate, the first region being included in an optical interference area of a first light and a second light on the substrate, the first light passing through a first passing portion of a diffraction mask and the second light passing through a second passing portion of the diffraction mask; and
exposing the first film to optical interference light generated by at least the first light and the second light.

2. The method according to claim 1, wherein the first region has a size smaller than a size of the optical interference area.

3. The method according to claim 1, wherein the first passing portion and the second passing portion are disposed side by side in a first direction on the diffraction mask.

4. The method according to claim 3, wherein the diffraction mask has a line-and-space pattern that includes a first passing portion and a second passing portion.

5. The method according to claim 1, wherein the first film is formed using one of an ink-jet printing method, a photogravure printing method, a screen printing method, and a micro-contact printing method.

6. The method according to claim 1, wherein the first light and the second light are emitted from a light source; and the diffraction mask is disposed between the light source and the substrate.

7. The method according to claim 1, wherein the first film is a negative-type photo-resist.

8. The method according to claim 1, wherein the diffraction mask includes a transparent substrate and a light blocking film.

9. The method according to claim 1, wherein the first film is exposed to direct images corresponding to the first passing portion and the second passing portion.

10. The method according to claim 1, wherein the first film is exposed to reversed images of the first passing portion and the second passing portion.

11. The method according to claim 1, comprising:
selectively forming a second film in a second region on the substrate, the second region being separated from the first region; and
exposing the second film to a third passed through a third passing portion of the diffraction mask.

12. The method according to claim 11, wherein the third passing portion has a size larger than a size of the second film.

13. The method according to claim 11, wherein the second film is formed in a shape of an alignment mark.

14. The method according to claim 11, wherein
the second film contains the same material as the first film, and
the second film is formed at the same time as the first film.

15. The method according to claim 14, wherein the first film and the second film are negative-type photo-resists.

16. The method according to claim 1, wherein the diffraction mask includes a first grating and a second grating separated from the first grating.

17. The method according to claim 16, wherein each of the first grating and the second grating includes slits having a stripe shape.

18. The method according to claim 1, wherein the first light and the second light pass through the first passing portion and the second passing portion after passing through another diffraction mask.

19. The method according to claim 18, wherein the diffraction mask includes a first grating and a second grating separated from the first grating, and is disposed between the another mask and the substrate.
